(19) United States
(12) Patent Application Publication
(10) Pub. No.: US 2025/0128215 A1
(43) Pub. Date: Apr. 24, 2025

(54) GAS MIXER

(71) Applicant: SAMSUNG ELECTRONICS CO., LTD., Suwon-si (KR)

(72) Inventors: Myeongjun GIL, Suwon-si (KR); Sunghyup KIM, Suwon-si (KR); Sebin CHOI, Suwon-si (KR)

(21) Appl. No.: 18/639,634

(22) Filed: Apr. 18, 2024

(30) Foreign Application Priority Data
Oct. 23, 2023 (KR) 10-2023-0141666

(51) Int. Cl. B01F 25/314; B01F 23/10; B01F 25/31; B01F 101/58

(52) U.S. Cl. CPC B01F 25/31434; B01F 23/10; B01F 25/311; B01F 2101/58

(57) ABSTRACT

A gas mixer may include a first gas channel, a first distribution channel, a second gas channel and a plurality of first connection channels. The first gas channel may be configured to supply a first gas into a reaction chamber. The first distribution channel may surround the first gas channel and is configured to uniformly distribute a second gas within the first distribution channel. The second gas channel may be configured to supply the second gas into the first distribution channel. The plurality of the first connection channels may be connected between the first distribution channel and the first gas channel. Thus, the second gas may be uniformly distributed in the cylindrical first distribution channel. The second gas may then be supplied to the first gas channel through the first connection channels. The second gas may be mixed with the first gas to form a mixed gas. As a result, the mixed gas may be uniformly distributed in the reaction chamber.

### CROSS-RELATED APPLICATION

This application claims priority under 35 USC § 119 to Korean Patent Application No. 10-2023-0141666, filed on Oct. 23, 2023 in the Korean Intellectual Property Office (KIPO), the disclosure of which is incorporated herein by reference in its entirety.

### BACKGROUND

### 1. Field

Example embodiments relate to a gas mixer. More particularly, example embodiments relate to a gas mixer configured to mix reaction gases used for manufacturing a semiconductor device.

### 2. Description of the Related Art

Generally, reaction gases used for manufacturing a semiconductor device may be mixed by a gas mixer to form a mixed gas. The mixed gas may be provided to a semiconductor substrate in a reaction chamber through a diffuser and a showerhead.

According to related arts, when the mixed gas over the semiconductor substrate may not be uniform, semiconductor chips formed from one semiconductor substrate may have different performances. The different performances of the semiconductor chips may result in decreasing a yield of the semiconductor device. Further, a purge gas, which may be introduced into the reaction chamber through the gas mixer, may also not be uniform. A removal ratio of particles by the purge gas may be reduced. The particles may damage the semiconductor chip to decrease the yield of the semiconductor device.

### SUMMARY

Example embodiments provide a gas mixer that may be capable of uniformly distributing a mixed gas over a semiconductor substrate.

According to example embodiments, there may be provided a gas mixer. The gas mixer may include a first gas channel, a first distribution channel, a second gas channel and a plurality of first connection channels. The first gas channel may be configured to supply a first gas into a reaction chamber. The first distribution channel may surround the first gas channel and is configured to uniformly distribute a second gas within the first distribution channel. The second gas channel may be configured to supply the second gas into the first distribution channel. The first distribution channel is in fluid communication with the first gas channel via the plurality of first connection channels such that the second gas can be introduced into the first gas channel.

According to example embodiments, there may be provided a gas mixer. The gas mixer may include a first gas channel, a first distribution channel, a second gas channel, a plurality of first connection channels, a second distribution channel, a third gas channel and a plurality of second connection channels. The first gas channel may be configured to supply a first gas into a reaction chamber. The first distribution channel may have a cylindrical shape configured to surround the first gas channel, and the first distribution channel is configured to uniformly distribute a second gas therewithin. The second gas channel may be configured to supply the second gas into the first distribution channel. The first distribution channel is in fluid communication with the first gas channel via the plurality of first connection channels such that the second gas can be introduced into the first gas channel. The second distribution channel may have a cylindrical shape configured to surround the first distribution channel, and the second distribution channel is configured to uniformly distribute a third gas therewithin. The third gas channel may be configured to supply the third gas into the second distribution channel. The second distribution channel is in fluid communication with the first gas channel via the plurality of second connection channels such that the third gas can be introduced into the first gas channel.

According to example embodiments, the second gas may be uniformly distributed in the cylindrical first distribution channel. The second gas may then be supplied to the first gas channel through the first connection channels. The second gas may be mixed with the first gas to form a mixed gas. Thus, the mixed gas may be uniformly distributed in the reaction chamber.

Further, the second gas may be distributed in the first distribution channel and the third gas may be distributed in the second distribution channel. Thus, generations of particles, which may be caused by mixing at least two different gases with each other, may be suppressed. As a result, a removal ratio of the particles by a purge gas may be improved.

According to example embodiments, a gas mixer includes a first gas channel configured to supply a first gas to a reaction chamber, a first distribution channel extending around the first gas channel, a second gas channel configured to supply a second gas to the first distribution channel, and a plurality of first connection channels. The first distribution channel is in fluid communication with the first gas channel via the plurality of first connection channels such that the second gas in the first distribution channel mixes with the first gas in the first gas channel, and the plurality of the first connection channels are uniformly spaced apart from each other.

### BRIEF DESCRIPTION OF THE DRAWINGS

Example embodiments will be more clearly understood from the following detailed description taken in conjunction with the accompanying drawings. FIGS. 1 to 7 represent non-limiting, example embodiments as described herein.

FIG. 1 is an exploded perspective view illustrating a gas mixer in accordance with example embodiments;

FIG. 2 is a perspective view illustrating the gas mixer in FIG. 1;

FIG. 3 is a partially cut perspective view illustrating the gas mixer in FIG. 2;

FIG. 4 is a cross-sectional view taken along line A-A′ in FIG. 3;

FIG. 5 is a perspective view illustrating a gas mixer in accordance with example embodiments;

FIG. 6 is a partially cut perspective view illustrating the gas mixer in FIG. 5; and

FIG. 7 is a cross-sectional view taken along line B-B′ in FIG. 6.

### DETAILED DESCRIPTION OF THE EMBODIMENTS

Hereinafter, example embodiments will be explained in detail with reference to the accompanying drawings.

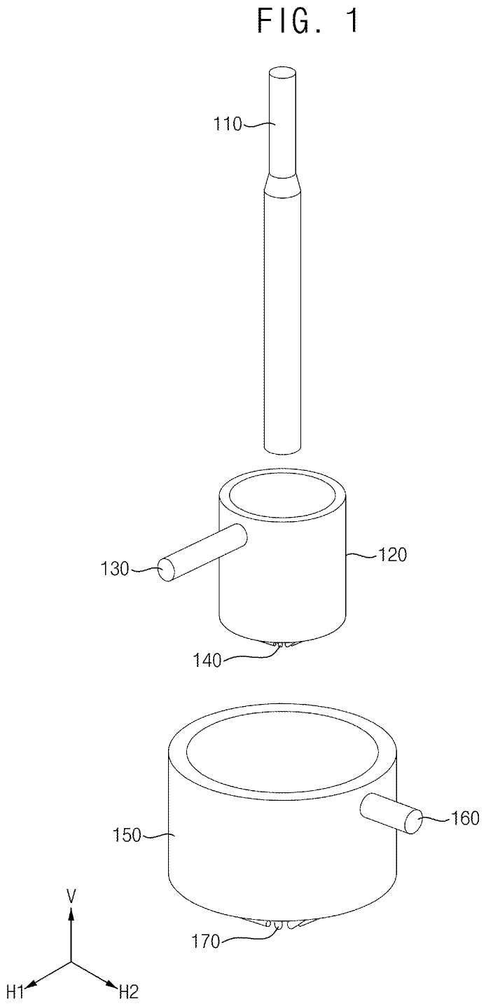

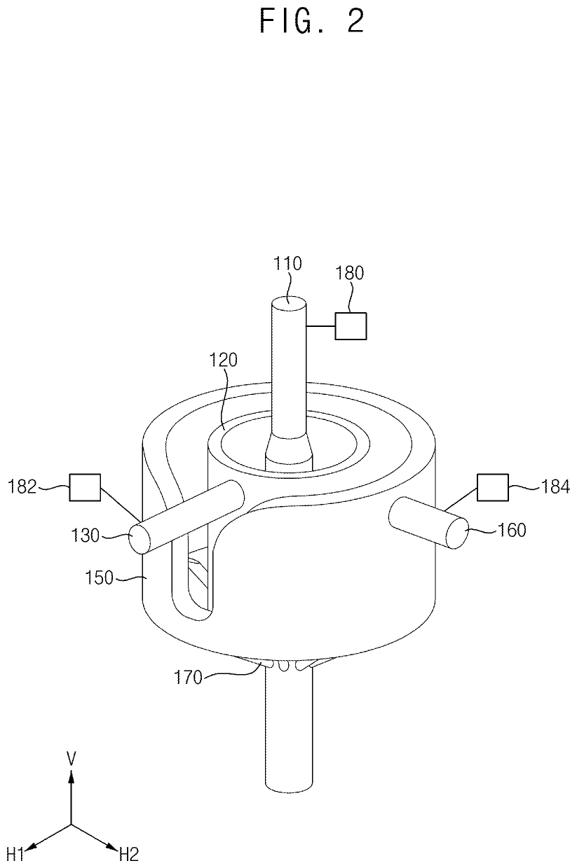

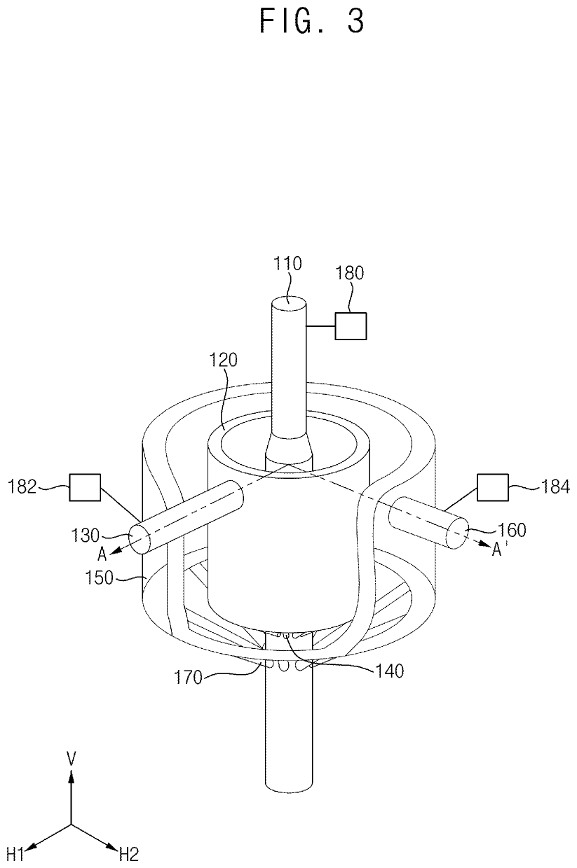

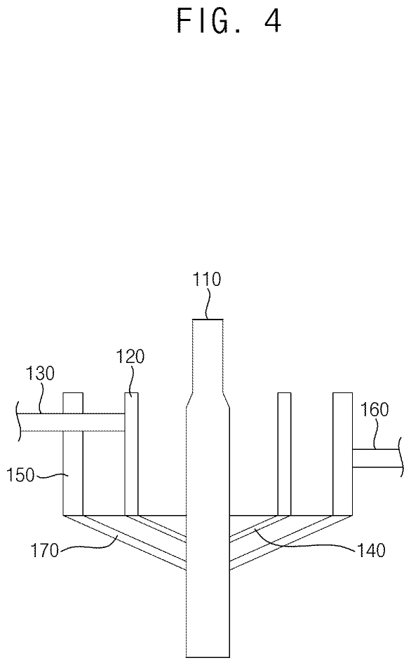

FIG. 1 is an exploded perspective view illustrating a gas mixer in accordance with example embodiments, FIG. 2 is a perspective view illustrating the gas mixer in FIG. 1, FIG. 3 is a partially cut perspective view illustrating the gas mixer in FIG. 2 and FIG. 4 is a cross-sectional view taken along line A-A′ in FIG. 3.

Referring to FIGS. 1 to 4, a gas mixer of example embodiments may include a first gas channel 110, a first distribution channel 120, a second gas channel 130, a plurality of first connection channels 140, a second distribution channel 150, a third gas channel 160, a plurality of second connection channels 170 and first to third temperature controllers 180, 182 and 184.

The first gas channel 110 may be arranged over a reaction chamber. The first gas channel 110 may be extended in a vertical direction V. The first gas channel 110 may be connected to the reaction chamber. That is, a lower end of the first gas channel 110 may be connected to the reaction chamber. A first gas may be supplied to the reaction chamber through the first gas channel 110.

The first temperature controller 180 may control a temperature of the first gas channel 110. That is, the first temperature controller 180 may control a temperature of the first gas supplied through the first gas channel 110. The first temperature controller 180 may control the temperature of the first gas using a cooling water, a heating coil, etc., but not limited thereto.

The first distribution channel 120 may surround the first gas channel 110. The first distribution channel 120 may uniformly distribute a second gas. That is, the second gas may be uniformly distributed in the first distribution channel 120. In example embodiments, the first distribution channel 120 may have a cylindrical shape, but is not limited thereto. That is, the first distribution channel 120 may have an annular cross-sectional shape having a hollow structure. Alternatively, the first distribution channel 120 may have a rectangular frame (or other polygonal) cross-sectional shape.

The second gas channel 130 may be connected to the first distribution channel 120 to supply the second gas into the first distribution channel 120. The second gas channel 130 may be extended in a first horizontal direction H1 substantially perpendicular to the vertical direction V, but not limited thereto.

The second temperature controller 182 may control a temperature of the first distribution channel 120. Particularly, the second temperature controller 182 may control a temperature of the second gas uniformly distributed in the first distribution channel 120. The second temperature controller 182 may control the temperature of the second gas using a cooling water, a heating coil, etc., but not limited thereto.

The first connection channels 140 may be connected between the first distribution channel 120 and the first gas channel 110, i.e., the first distribution channel 120 is in fluid communication with the first gas channel 110 via the first connection channels 140. The second gas uniformly distributed in the first distribution channel 120 may be supplied to the first gas channel 110 through the first connection channels 140. Thus, the second gas may be mixed with the first gas in the first gas channel 110.

Each of the first connection channels 140 may include a first end and a second end. The first end may be connected to a lower surface of the first distribution channel 120 such that the respective first connection channel is in fluid communication with the first distribution channel 120 (i.e., through a lower wall of the first distribution channel 120). The second end may be connected to the first gas channel 110 such that the respective first connection channel is in fluid communication with the first gas channel 110. In example embodiments, the first end may be positioned higher than the second end, i.e., the first end is above the second end relative to the first gas channel 110. That is, the first end may correspond to an upper end of the first connection channel 140. The second end may correspond to a lower end of the first connection channel 140.

Further, the first connection channels 140 may be spaced apart from each other by a uniform gap, i.e., the first connection channels 140 are uniformly spaced apart. Particularly, the upper ends of the first connection channels 140 may be uniformly spaced apart from each other by a first gap. The lower ends of the first connection channels 140 may be uniformly spaced apart from each other by a second gap narrower than the first gap. Thus, the first connection channels 140 may be radially extended from the first gas channel 110 toward the first distribution channel 120. As a result, the second gas may be uniformly supplied to the first gas channel 110 through the first connection channels 140.

The second distribution channel 150 may surround the first distribution channel 120. The second distribution channel 150 may uniformly distribute a third gas therewithin. That is, the third gas may be uniformly distributed in the second distribution channel 150. In example embodiments, the second distribution channel 150 may have a cylindrical shape having a diameter longer than a diameter of the first distribution channel 120, but not limited thereto. That is, the second distribution channel 150 may have an annular cross-sectional shape having a hollow structure. Alternatively, the second distribution channel 150 may have a rectangular frame cross-sectional (or other polygonal) shape.

In example embodiments, the second distribution channel 150 may have an upper surface substantially coplanar with an upper surface of the first distribution channel 120 as illustrated in FIG. 2, but is not limited thereto. Further, the second distribution channel 150 may have a lower surface lower than a lower surface of the first distribution channel 120. That is, the second distribution channel 150 may have a height higher than a height of the first distribution channel 120.

The third gas channel 160 may be connected to the second distribution channel 150 to supply the third gas into the second distribution channel 150. The third gas channel 160 may be extended in a second horizontal direction H2 substantially perpendicular to the first horizontal direction H1, but not limited thereto. In example embodiments, the third gas channel 160 may be positioned at a height or elevation substantially the same as a height or elevation of the second gas channel 130, but is not limited thereto.

The third temperature controller 184 may control a temperature of the second distribution channel 150. Particularly, the third temperature controller 184 may control a temperature of the third gas uniformly distributed in the second distribution channel 150. The third temperature controller 184 may control the temperature of the second gas using a cooling water, a heating coil, etc., but not limited thereto.

According to example embodiments, the temperatures of the first to third gases may be independently controlled by the first to third temperature controllers 180, 182, 184. Thus, dissociations of the first to third gases in the first and second distribution channels 120 and 150 may be suppressed. As a result, generations of particles from the first to third dissociated gases may also be suppressed.

The second connection channels 170 may be connected between the second distribution channel 150 and the first gas channel 110, i.e., the second distribution channel 150 is in fluid communication with the first gas channel 110 via the second connection channels 170. The third gas uniformly distributed in the second distribution channel 150 may be supplied to the first gas channel 110 through the second connection channels 170. Thus, the third gas may be mixed with the first and second gases in the first gas channel 110.

Each of the second connection channels 170 may include a first end and a second end. The first end may be connected to a lower surface of the second distribution channel 150 such that the respective second connection channel is in fluid communication with the second distribution channel 150 (i.e., through a lower wall of the second distribution channel 150). The second end may be connected to the first gas channel 110. In example embodiments, the first end may be positioned higher than the second end, i.e., the first end is above the second end relative to the first gas channel 110. That is, the first end may correspond to an upper end of the second connection channel 170. The second end may correspond to a lower end of the second connection channel 170.

Further, the second connection channels 170 may be spaced apart from each other by a uniform gap, i.e., the second connection channels 170 are uniformly spaced apart. Particularly, the upper ends of the second connection channels 170 may be uniformly spaced apart from each other by a first gap. The lower ends of the second connection channels 170 may be uniformly spaced apart from each other by a second gap narrower than the first gap. Thus, the second connection channels 170 may be radially extended from the first gas channel 110 toward the second distribution channel 150. As a result, the third gas may be uniformly supplied to the first gas channel 110 through the second connection channels 170.

As mentioned above, because the lower surface of the second distribution channel 150 may be positioned under the lower surface of the first distribution channel 120, the second connection channels 170 may also be positioned under the first connection channel 140. Thus, a mixed point of the first to third gases in the first gas channel 110 may be positioned under a mixed point of the first and second gases in the first gas channel 110.

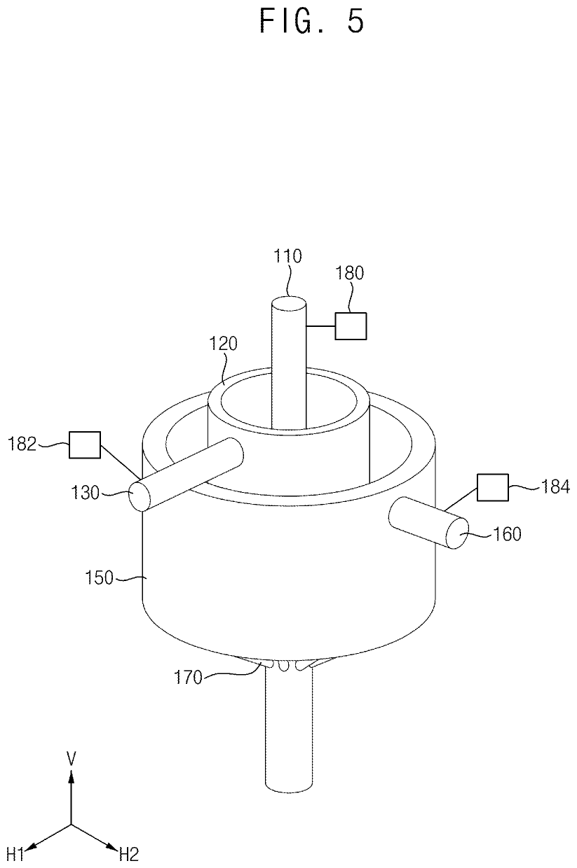

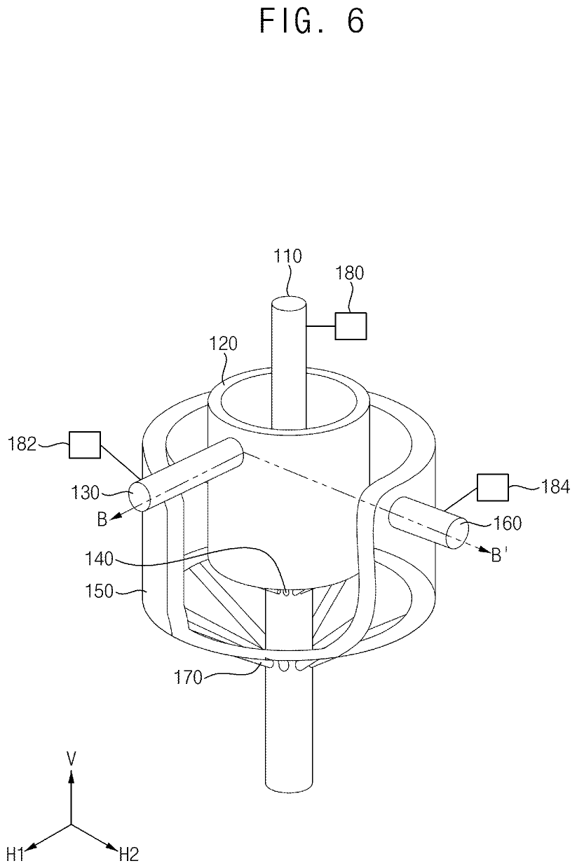

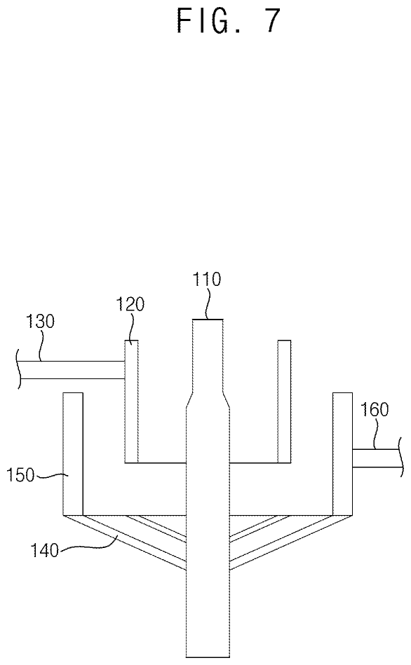

FIG. 5 is a perspective view illustrating a gas mixer in accordance with example embodiments, FIG. 6 is a partially cut perspective view illustrating the gas mixer in FIG. 5 and FIG. 7 is a cross-sectional view taken along line B-B′ in FIG. 5.

A gas mixer of example embodiments may include elements substantially the same as those of the gas mixer in FIG. 3 except for a position of a first distribution channel. Thus, the same reference numerals may refer to the same elements and any further illustrations with respect to the same elements may be omitted herein for brevity.

Referring to FIGS. 5 to 7, an upper surface of the first distribution channel 120 may be upwardly protruded from an upper surface of the second distribution channel 150. That is, the upper surface of the first distribution channel 120 may be positioned over (i.e., at a higher elevation than) the upper surface of the second distribution channel 150. Thus, the second gas channel 130 connected to the first distribution channel 120 may also be positioned over the third gas channel 160 connected to the second distribution channel 150.

Therefore, because the second gas channel 130 and the third gas channel 160 may be positioned on different planes, interference between the second gas channel 130 and the third gas channel 160 may be prevented.

According to example embodiments, the second gas may be uniformly distributed in the cylindrical first distribution channel. The second gas may then be supplied to the first gas channel through the first connection channels. The second gas may be mixed with the first gas to form a mixed gas. Thus, the mixed gas may be uniformly distributed in the reaction chamber.

Further, the second gas may be distributed in the first distribution channel and the third gas may be distributed in the second distribution channel. Thus, generations of particles, which may be caused by mixing at least two different gases with each other, may be suppressed. As a result, a removal ratio of the particles by a purge gas may be improved.

The foregoing is illustrative of example embodiments and is not to be construed as limiting thereof. Although a few example embodiments have been described, those skilled in the art will readily appreciate that many modifications are possible in the example embodiments without departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A gas mixer comprising:
a first gas channel configured to supply a first gas to a reaction chamber;
a first distribution channel surrounding the first gas channel, wherein the first distribution channel is configured to uniformly distribute a second gas within the first distribution channel;
a second gas channel configured to supply the second gas to the first distribution channel; and
a plurality of first connection channels, wherein the first distribution channel is in fluid communication with the first gas channel via the plurality of first connection channels.

2. The gas mixer of claim 1, wherein the first distribution channel has a cylindrical shape.

3. The gas mixer of claim 1, wherein the first gas channel extends along a first direction and the second gas channel extends along a second direction that is substantially perpendicular to the first direction.

4. The gas mixer of claim 1, wherein each of the plurality of the first connection channels comprises:
a first end in fluid communication with the first distribution channel through a lower wall of the first distribution channel; and
a second end in fluid communication with the first gas channel.

5. The gas mixer of claim 4, wherein the first end is positioned above the second end.

6. The gas mixer of claim 1, wherein the plurality of the first connection channels are uniformly spaced apart from each other.

7. The gas mixer of claim 3, further comprising:
a second distribution channel surrounding the first distribution channel, wherein the second distribution channel is configured to uniformly distribute a third gas within the second distribution channel;
a third gas channel configured to supply the third gas to the second distribution channel; and
a plurality of second connection channels, wherein the second distribution channel is in fluid communication with the first gas channel via the plurality of second connection channels.

8. The gas mixer of claim 7, wherein the second distribution channel has a cylindrical shape.

9. The gas mixer of claim 7, wherein a lower surface of the second distribution channel is under a lower surface of the first distribution channel.

10. The gas mixer of claim 7, wherein the third gas channel and the second gas channel are at different elevations relative to the first gas channel.

11. The gas mixer of claim 7, wherein the third gas channel extends along a third direction that is substantially perpendicular to the second direction.

12. The gas mixer of claim 7, wherein each of the plurality of the second connection channels comprises:
a first end in fluid communication with the second distribution channel through a lower wall of the second distribution channel; and
a second end in fluid communication with the first gas channel.

13. The gas mixer of claim 12, wherein the first end is positioned above the second end.

14. The gas mixer of claim 7, wherein the plurality of the second connection channels are uniformly spaced apart from each other.

15. A gas mixer comprising:
a first gas channel configured to supply a first gas to a reaction chamber;
a first distribution channel having a cylindrical shape, wherein the first distribution channel surrounds the first gas channel and is configured to uniformly distribute a second gas within the first distribution channel;
a second gas channel configured to supply the second gas to the first distribution channel;
a plurality of first connection channels, wherein the first distribution channel is in fluid communication with the first gas channel via the plurality of first connection channels;
a second distribution channel having a cylindrical shape, wherein the second distribution channel surrounds the first distribution channel and is configured to uniformly distribute a third gas within the second distribution channel;
a third gas channel configured to supply the third gas to the second distribution channel; and
a plurality of second connection channels, wherein the second distribution channel is in fluid communication with the first gas channel via the plurality of second connection channels.

16. The gas mixer of claim 15, wherein the first gas channel extends along a first direction, the second gas channel extends along a second direction that is substantially perpendicular to the first direction and the third gas channel extends along a third direction that is substantially perpendicular to the second direction.

17. The gas mixer of claim 15, wherein the third gas channel and the second gas channel are at different elevations relative to the first gas channel.

18. The gas mixer of claim 15, wherein a lower surface of the second distribution channel is under a lower surface of the first distribution channel.

19. The gas mixer of claim 15, wherein the plurality of the first connection channels are uniformly spaced apart from each other, and the plurality of the second connection channels are uniformly spaced apart from each other.

20. A gas mixer comprising:
a first gas channel configured to supply a first gas to a reaction chamber;
a first distribution channel extending around the first gas channel;
a second gas channel configured to supply a second gas to the first distribution channel; and
a plurality of first connection channels, wherein the first distribution channel is in fluid communication with the first gas channel via the plurality of first connection channels such that the second gas in the first distribution channel mixes with the first gas in the first gas channel, and wherein the plurality of the first connection channels are uniformly spaced apart from each other.
